(19) United States
(12) Patent Application Publication
(10) Pub. No.: US 2007/0262429 A1
(43) Pub. Date: Nov. 15, 2007

(54) Perimeter stacking system and method

(75) Inventor: Paul Goodwin, Austin, TX (US)

Correspondence Address: FISH & RICHARDSON P.C., P.O BOX 1022, Minneapolis, MN, 55440-1022, US

(73) Assignee: Staktek Group, L.P.

(21) Appl. No.: 11/434,405

(22) Filed: May 15, 2006

(51) Int. Cl. H01L 21/00

(52) U.S. Cl. 257/678; 438/106

(57) ABSTRACT

A stacked module employs flexible circuitry to connect CSP integrated circuits. A flexible circuit with obverse and reverse sides is disposed between two CSPs oriented face-to-face with the flex circuit between to form a precursor assembly. One or more flaps or extension parts of the flex circuitry extend from the perimeter of the facing CSPs. Contacts to connect the CSPs to an operating environment are disposed along the one or more flex circuitry flaps or extensions. In a preferred embodiment, the CSP and flex circuit precursor assembly is disposed in a frame and the one or more flex circuitry flaps or extensions that extend out from beyond the perimeter of the CSP devices are disposed on the form or frame. The module contacts disposed on the flex circuitry extension(s) are positioned along the bottom edge of the form or frame for deployment of the stacked module in an operating environment.

### TECHNICAL FIELD

The present invention relates to aggregating integrated circuits and, in particular, to stacking integrated circuits in chip-scale packages and methods for creating stacked modules of chip-scale packages.

### BACKGROUND

A variety of techniques are used to stack packed integrated circuits. Some methods require special packages, while other techniques stack packages configured for stand-alone deployment in an operating environment.

“Chip scale packaging” or CSP refers generally to packages that provide connection to an integrated circuit through a set of contacts (often embodied as “bumps” or “balls”) arrayed across a major surface of the package. Instead of leads emergent from a peripheral side of the package as in “leaded” packages, in a CSP, contacts are placed on a major surface and typically emerge from the planar bottom surface of the package. The absence of “leads” on package sides renders most stacking techniques devised for leaded packages inapplicable for CSP stacking.

CSP has enabled reductions in size and weight parameters for many applications. CSP is a broad category including a variety of packages from near chip scale to die-sized packages such as the die sized ball grid array (DSBGA). To meet the continuing demands for cost and form factor reductions concurrent with increasing capabilities and capacities, technologies that aggregate plural integrated circuit dies in a package been developed. The techniques and technology for stacking plural integrated circuit dies within a single package, however, are not generally applicable for stacking packages that are configured to allow stand-alone deployment in an operating environment.

There are several known techniques for stacking integrated circuit packages articulated in chip scale technology. A variety of previous techniques for stacking CSPs typically present complex structural arrangements and thermal or high frequency performance issues. For example, thermal performance is a characteristic of importance in CSP stacks. With increasing operating frequencies of most systems, high frequency performance issues are also increasingly important. Further, many stacking techniques result in modules that exhibit profiles taller than may be preferred for particular applications.

The industry has developed a variety of stacked module designs. Some of those designs employ flexible circuitry to connect stacked chip scale IC devices. Typically, such flex-based stack designs place a part of the flex circuitry beneath the stack and part of the flex circuitry between constituent ICs of the stack disposed in like orientations. This can result in unequal trace length. Further, typical CSP stack designs use solder balls to mount the assembly to the host platform. Thus, in some cases where such proven designs are present, a height penalty is paid. Consequently, alternatives are welcome.

Stacked module design and assembly techniques and systems that provide a thermally efficient, reliable structure that perform well at higher frequencies but do not add excessive height to the stack that can be manufactured at reasonable cost with readily understood and managed materials and methods are provided.

### SUMMARY

A stacked module employs flexible circuitry to connect CSP integrated circuits. A flexible circuit with obverse and reverse sides is disposed between two CSPs oriented face-to-face with the flex circuit between to form a precursor assembly. One or more flaps or extension parts of the flex circuitry extend from the perimeter of the facing CSPs. Contacts to connect the CSPs to an operating environment are disposed along the one or more flex circuitry flaps or extensions.

In a preferred embodiment, the CSP and flex circuit precursor assembly is disposed in a frame and the one or more flex circuitry flaps or extensions that extend out from beyond the perimeter of the CSP devices are disposed on the form or frame. The contacts disposed on the flex circuitry extension(s) are positioned along the bottom edge of the form or frame for deployment of the stacked module in an operating environment.

The present invention may be employed to advantage in numerous configurations and combinations of CSPs in modules provided for high-density memories, high capacity computing, and other applications. The present invention also provides methods for constructing stacked circuit modules and precursor assemblies with flexible circuitry.

### BRIEF DESCRIPTION OF THE SEVERAL VIEWS OF THE DRAWINGS

FIG. 1 is a cross-sectional view of a module devised in accordance with a preferred embodiment of the present invention.

FIG. 2 is a plan view of module devised in accordance with a preferred embodiment of the present invention.

FIG. 3 is a plan view of a lower side of a module devised in accordance with a preferred embodiment of the present invention.

FIG. 4 depicts a precursor assembly for a module devised in accordance with a preferred embodiment of the present invention.

FIG. 5 depicts a step in a method for constructing a module in accordance with a preferred embodiment of the present invention.

FIG. 6 depicts an alternative preferred step in a method for constructing a module in accordance with the present invention.

FIG. 7A depicts a module constructed in accordance with a preferred embodiment of the present invention.

FIG. 7B depicts a module constructed in accordance with a preferred embodiment of the present invention.

FIG. 8 is a cross-sectional depiction of a multiple layer flex circuit employed in a preferred embodiment of the present invention.

### DETAILED DESCRIPTION OF PREFERRED EMBODIMENTS

The present invention can be used to advantage with CSP packages of a variety of sizes and configurations ranging from typical BGAs with footprints somewhat larger than the contained die to smaller packages such as, for example, die-sized packages such as DSBGA. Although the present invention is applied most frequently to chip scale packages that contain one die, it may be employed with chip scale packages that include more than one integrated circuit die.

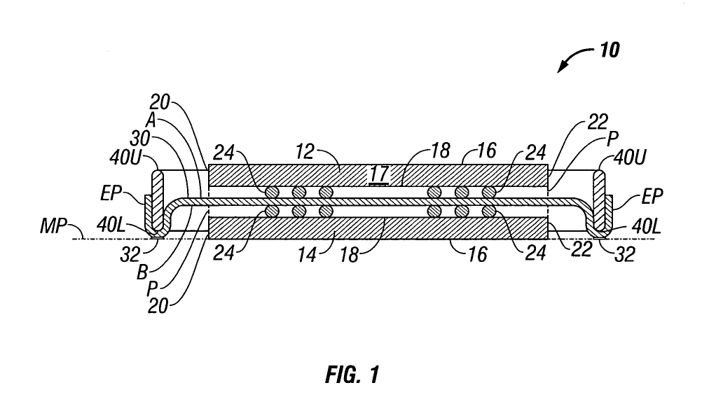

FIG. 1 is an elevation view of module 10 devised in accordance with a preferred embodiment of the present invention. Module 10 is comprised of upper CSP 12 and lower CSP 14 which, as shown, are stacked with flex circuitry 30 (“flex”, “flex circuit” or “flexible circuit structure”) between. Each of CSPs 12 and 14 have an upper surface 16 and a lower surface 18 and opposite lateral sides 20 and 22 of respective bodies 17. As shown, CSPs 12 and 14 are disposed facing each other with respective lower faces 18 of the CSPs 12 and 14 facing toward each other. Lateral sides 20 and 22 may be in the character of sides or may, if the CSP is especially thin, be in the character of an edge.

CSP packages of a variety of types and configurations may be employed in preferred embodiments of the invention. CSPs such as, for example, those that are die-sized, as well those that are near chip-scale as well as the variety of ball grid array packages known in the art may be employed. Collectively, these will be known herein as chip scale packaged integrated circuits (CSPs) and preferred embodiments will be described in terms of CSPs, but the particular configurations used in the explanatory figures are not, however, to be construed as limiting. For example, the views of certain FIGS. herein are depicted with CSPs of a particular profile, but it should be understood that the figures are exemplary only. The invention may be employed to advantage in the wide range of CSP configurations available in the art where an array of connective elements is available from at least one major surface. The invention is advantageously employed with CSPs that contain memory circuits but may be employed to advantage with logic, computing, and other types of circuits where added capacity without commensurate PWB or other board surface area consumption is desired.

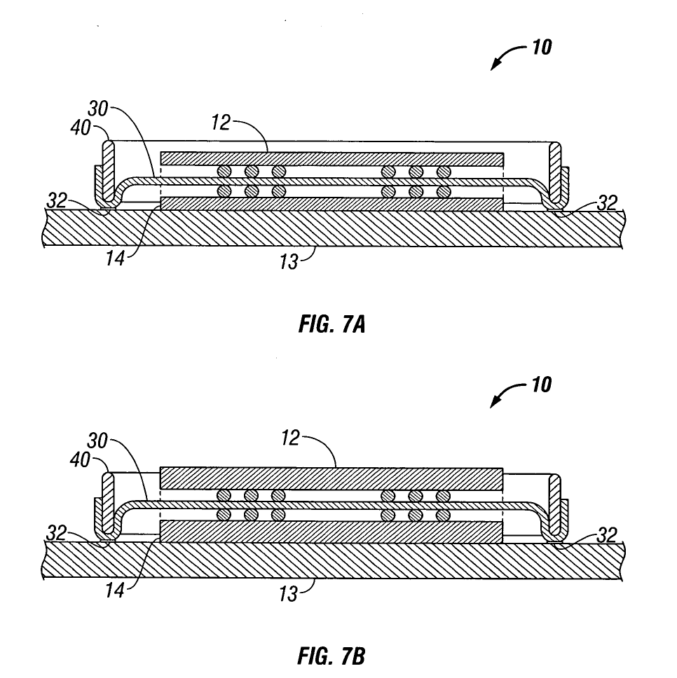

Typical CSPs, such as, for example, ball-grid-array (“BGA”), micro-ball-grid array (“μBGA”), and fine-pitch ball grid array (“FBGA”) packages have an array of connective contacts embodied, for example, as leads, bumps, solder balls, pads or balls along lower surface 18 of a plastic casing in any of several patterns and pitches (“contacts”). An external portion of the connective contacts is often finished with a ball of solder. Shown in FIG. 1 are CSP contacts 24 along lower surfaces 18 of CSPs 12 and 14. As shown, CSP contacts 24 on each of upper CSP 12 and lower CSP 14 are connected to flexible circuitry 30 that is disposed between the respective lower surfaces of CSPs 12 and 14 and emerges from the perimeter P of bodies 17 defined in part by lateral sides 20 and 22. In the cross-sectional view of FIG. 1, frame 40 is shown with upper edge 40U and lower edge 40L about which extension parts E of flex circuitry 30 are disposed to position module contacts 32 along a mounting plane “MP” that may or may not coincide with the upper surface 16 of CSP 14. Where plane MP coincides with upper surface 16 of CSP 14, the upper surface of CSP 16 maybe in contact with an application environment mounting area such as is shown in later FIGS. 7.

Frame 40 may be comprised of any of a large variety of materials with some preferred materials being thermally conductive. Plastic may also be used to create frame 40 in those embodiments where light weight and ease of fabrication are of concern. Further, frame 40 need not be contiguous and need not circumvent the entirety of the perimeter of the respective CSPs.

Flex circuitry 30 has two major sides “A” and “B”, along each of which there are disposed contact sites for connection of integrated circuits such as CSPs 12 and 14 as those of skill will understand often appreciation of this specification. One or more conductive layers may be employed in flex circuitry 30. The entire flex circuit may be flexible or, as those of skill in the art will recognize, a PCB structure made flexible in, for example, extension areas E to allow conformability around frame 40 as shown and rigid in other areas, such as the area between respective bodies 17 of CSPs 12 and 14 may be employed as an alternative flex circuit in the present invention. For example, structures known as rigid-flex may be employed.

Flex circuitry 30 is preferably a multi-layer flexible circuit structure that has at least two conductive layers. Preferably, the conductive layers are metal such as alloy 110. The use of plural conductive layers provides advantages such as, for example, the creation of a distributed capacitance intended to reduce noise or bounce effects that can, particularly at higher frequencies, degrade signal integrity, as those of skill in the art will recognize. However, a flex circuitry having a single conductive layer may also be employed in module 10.

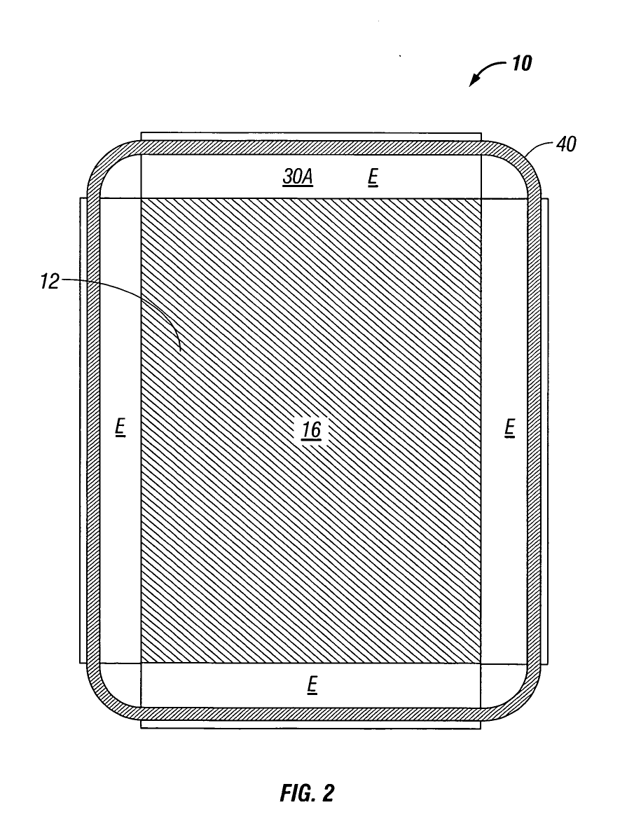

FIG. 2 is a plan view of exemplar module 10 from above. Upper side 16 of upper CSP 12 is visible while extension parts E of flexible circuitry 30 emerge from perimeter P of bodies 17 of the respective CSPs.

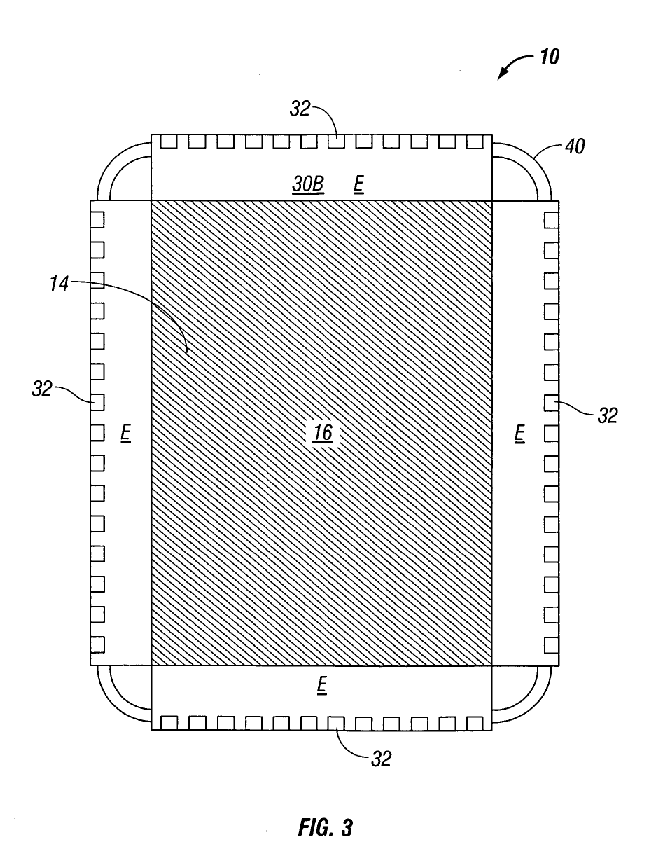

FIG. 3 is a plan view from below of module 10 devised in accordance with a preferred embodiment of the present invention. Upper side 16 of lower CSP 14 is visible as are parts of frame 40 visibly emergent from the flex circuitry. Module contacts 32 are exhibited along extension parts E of flex circuit 30.

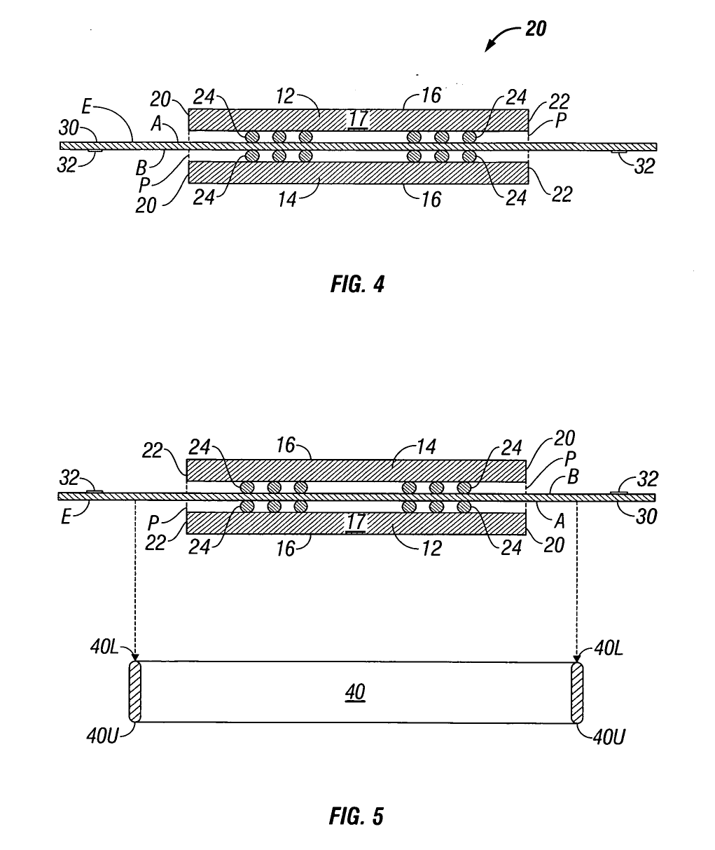

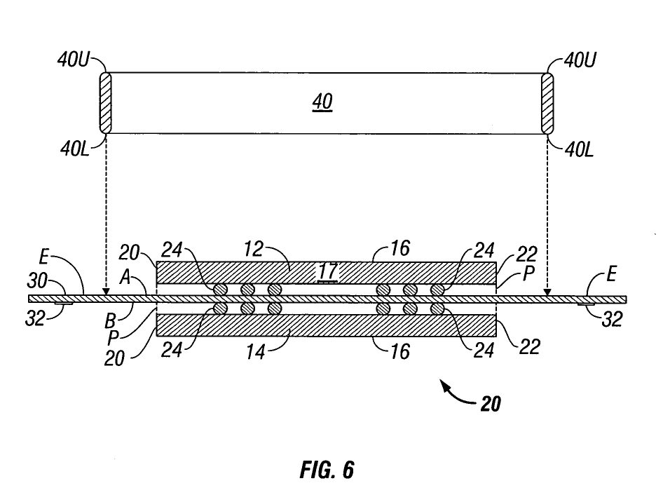

Steps in a preferred method for fabricating modules such as the module 10 depicted in FIGS. 1 and 2, are shown in FIGS. 4, 5 and 6. As shown in FIG. 4, CSPs 12 and 14 are connected to respective major sides A and B of flex circuitry 30 by techniques already familiar to those of skill in the art. Extension parts E of flex circuitry 30 are emergent from the bodies 17 of the respective CSPs. As shown in FIG. 5, the resulting precursor assembly 20 of CSPs and flex circuitry is set into frame 40 with extension parts E disposed over frame 40 to place module contacts 32 along edge 40L of frame 40. In alternative techniques, an example of which is shown in FIG. 6, frame 40 is set down over precursor assembly 20 while the parts EP of extension parts E that extend beyond the frame 40 are brought up the side of frame 40 as shown in earlier FIG. 1.

FIGS. 7A and 7B depict preferred modules 10 with 7A having CSPs 12 and 14 that are “thinner” than are the CSPs 12 and 14 depicted in FIG. 7B.

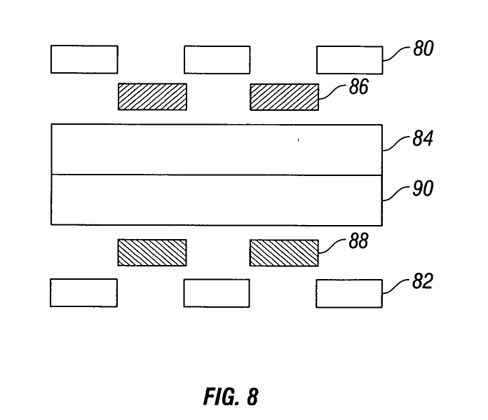

Flex 30 is shown in FIG. 8 to be comprised of multiple layers. Flex 30 has a first outer surface 80 and a second outer surface 82. Flex circuit 30 preferably has at least two conductive layers interior to first and second outer surfaces 80 and 82. In the depicted preferred embodiment, first conductive layer 86 and second conductive layer 88 are interior to first and second outer surfaces 80 and 82. Intermediate layer 84 and adhesive dielectric 90 lie between first conductive layer 86 and second conductive layer 88. There may be more than one intermediate layer, and polyimide is the preferred material for intermediate layer(s).

Although the present invention has been described in detail, it will be apparent to those skilled in the art that the invention may be embodied in a variety of specific forms and that various changes, substitutions and alterations can be made without departing from the spirit and scope of the invention. The described embodiments are only illustrative and not restrictive, and therefore the scope of the invention is indicated by the following claims.

1. A stacked integrated circuit module comprising:
a first CSP having a body with a first major side and a second major side along which are plural CSP contacts and the first CSP having at least two lateral sides and a perimeter;
a second CSP having a body with a first major side and a second major side along which are plural CSP contacts and the second CSP having at least two lateral sides and a perimeter, the first and second CSPs being oriented in stacked disposition with respective second major sides facing toward each other;
flex circuitry disposed between and connected to the first and second CSPs, the flex circuitry having one or more flex circuitry extension parts emergent from the perimeters of the respective first and second CSPs; and
a frame over which the one or more extension parts of the flex circuitry are disposed.

2. The stacked integrated circuit module of claim 1 further comprising plural module contacts disposed along at least one of the one or more flex circuitry extension parts emergent from the perimeters of the respective first and second CSPs.

3. The stacked integrated circuit module of claims 1 or 2 in which the frame has an upper and lower edge, the plural module contacts being disposed along the lower edge of the frame.

4. The stacked integrated circuit module of claims 2 or 3 in which the plural module contacts are disposed along a common mounting plane.

5. The stacked integrated circuit module of claims 1, 2, 3, or 4 in which the flex circuitry has two conductive layers.

6. The stacked integrated circuit module of claim 1 in which the frame is comprised of thermally conductive material.

7. The stacked integrated circuit module of claim 1 in which the frame is comprised of plastic.

8. The stacked integrated circuit module of claim 1 in which the one or more extension parts of the flex circuitry emerge from beyond the first and second CSP bodies on each perimeter side.

9. The stacked circuit module of claim 1 in which the frame does not entirely surround the perimeter of the first and second CSPs.

10. A method for stacking integrated circuits, the method comprising the steps of:
providing first and second CSPs each of which have a body with a perimeter;
providing a flex circuit larger than the perimeter of the bodies of the respective first and second CSPs;
connecting the first CSP to a first side of a flex circuit and connecting the second CSP to second side of the flex circuit;
providing a frame; and
disposing the first and second CSPs and flex circuit into the frame so that at least a part of the flex circuit is disposed over the frame.

11. The method of claim 10 in which there are module contacts on the part of the flex circuit disposed over the frame.

12. The method of claim 10 in which the flex circuit has two conductive layers.

13. The method of claim 10 in which the frame is comprised of thermally conductive material.

14. The method of claim 10 in which the frame is comprised of plastic.

15. The method of claim 10 in which there are module contacts on the part of the flex circuit disposed over the frame and said module contacts are positioned along an edge of said frame.

16. The method of claim 10 in which the frame does not entirely surround the perimeter of the lowermost of the first and second CSPs.

17. A method for stacking integrated circuits, the method comprising the steps of:
providing first and second CSPs each of which have a body with a perimeter;
providing a flex circuit having first and second sides and which is larger than the perimeter of the bodies of the respective first and second CSPs;
connecting the first CSP to the first side of a flex circuit and connecting the second CSP to the second side of the flex circuit;
providing a frame; and
disposing the frame over the frame so that at least a part of the flex circuit is disposed along an edge of the frame.

18. The method of claim 17 in which the part of the flex circuit disposed along the edge of the frame has module contacts.

19. The method of claim 17 in which the frame is comprised of plastic.

20. The method of claim 17 in which the frame is comprised of thermally conductive material.

21. The method of claim 17 in which the frame does not entirely surround the perimeter of the lowermost of the first and second CSPs.
